(19) United States
(12) Patent Application Publication
(10) Pub. No.: US 2011/0014396 A1
(43) Pub. Date: Jan. 20, 2011

(54) RECIRCULATING LINEAR ROLLING BUSHING

(75) Inventor: Alexander S. Polyak, San Jose, CA (US)

Correspondence Address: PATTERSON & SHERIDAN, LLP - - APPM/TX, 3040 POST OAK BOULEVARD, SUITE 1500, HOUSTON, TX, 77056, US

(73) Assignee: APPLIED MATERIALS, INC., Santa Clara, CA (US)

(21) Appl. No.: 12/836,484

(22) Filed: Jul. 14, 2010

Related U.S. Application Data
(60) Provisional application No. 61/225,469, filed on Jul. 14, 2009.

(51) Int. Cl. C23C 16/458; C23C 16/50

(52) U.S. Cl. 427/569; 269/289 R; 269/55

(57) ABSTRACT

A method and apparatus for a linear motion device is described. In one embodiment, linear motion device includes a housing having a bore formed therethrough along a longitudinal axis and at least two raceways formed at least partially in the housing having a plurality of bearing elements movably disposed therein. Each of the at least two raceways include a first channel disposed in a first radial plane relative to the longitudinal axis, and a second channel connected to the first channel and disposed in the first radial plane inward of the first channel, the second channel including a longitudinal slit allowing at least a portion of the plurality of bearing elements to extend into the bore.

### CROSS-REFERENCE TO RELATED APPLICATIONS

This application claims benefit of U.S. Provisional Patent Application Ser. No. 61/225,469, filed Jul. 14, 2009, which is hereby incorporated by reference.

### BACKGROUND OF THE INVENTION

1. Field of the Invention

Embodiments of the invention generally relate to a linear motion device for guiding a pin utilizing rolling friction. More particularly, embodiments of the invention relate to a linear motion device for guiding a lift pin in a chemical vapor deposition chamber.

2. Description of the Related Art

Electronic devices, such as thin film transistors (TFT's), photovoltaic (PV) devices or solar cells and other electronic devices have been fabricated on thin media for many years. The thin media is generally a discrete tile, a wafer, a sheet or other substrate having a major side with a surface area less than one square meter. However, there is an ongoing effort directed to fabricating the electronic devices on substrates having a surface area much greater than one square meter, such as two square meters, or larger, to produce an end product of a larger size and/or decrease fabrication costs per device (e.g., pixel, TFT, photovoltaic or solar cell, etc.).

The ever-increasing size of these substrates presents numerous handling challenges. The thin media is highly flexible at room temperature and becomes even more flexible at elevated processing temperatures. The flexibility of the thin media, along with the increased surface area, results in greater deflection and/or requires additional areas that must be supported to prevent excess deflection. Simply adding additional support points is not a desirable option due to the increased possibility of particle contamination.

Additionally, handling sometimes requires a dynamic positioning of the substrate using lift pins that are movable relative to a substrate supporting surface. During this dynamic positioning, the substrate may bend, bow or flex unexpectedly. This random deflection may produce torsional and/or lateral forces on the lift pins. These forces acting on the lift pins may cause one or more of the lift pins to bind, break, fail, scratch or otherwise damage the substrate, which may generate particles. The damage of a lift pin and/or a substrate causes system downtime and/or costly loss of product, which decreases throughput and profitability. While conventional bushings having movable lift pins for supporting substrates exist, the bushings are typically made from materials that are incompatible with the environment inside a deposition chamber. For example, the conventional bushings may be made of materials that cannot withstand temperatures in excess of 1000° C., and/or made of materials that react with process chemistries.

What is needed is a linear motion device for supporting a lift pin that is configured to withstand temperatures up to 1,000° C., not reactive with process chemistry and is adapted to withstand deflection, torsion and lateral forces acting on the lift pin while allowing movement of the lift pin with minimal friction.

### SUMMARY OF THE INVENTION

Embodiments described herein provide a method and apparatus for guiding a substrate support pin in a susceptor disposed in a vacuum chamber. In one embodiment, a support pedestal for a vacuum chamber is described. The support pedestal includes a body having a having a plurality of openings formed between two major sides of the body, and a roller bushing disposed in at least one of the plurality of openings. The roller bushing comprises a tubular body including an outer perimeter and a bore formed therethrough, at least three raceways formed at least partially in the body, the at least three raceways containing a plurality of bearing elements. Each of the at least three raceways comprise a first channel, and a second channel parallel to and radialy separated from the first channel, the second channel including a longitudinal slit allowing at least a portion of the plurality of bearing elements to extend into the bore, and a lift pin disposed in the bore.

In another embodiment, a support pedestal for a vacuum chamber is described. The support pedestal comprises an aluminum body having a having a plurality of openings formed between two major sides of the body, and a roller bushing disposed in at least one of the plurality of openings. The roller bushing comprises a housing having a bore formed therethrough along a longitudinal axis, at least two raceways formed at least partially in the housing having a plurality of bearing elements movably disposed therein. Each of the at least two raceways comprise a first channel disposed in a first radial plane relative to the longitudinal axis, and a second channel disposed in the first radial plane inward of the first channel, the second channel including a longitudinal slit allowing at least a portion of the plurality of bearing elements to extend into the bore, and a first cap disposed at a first end of the housing and a second cap disposed at a second end of the housing, each cap including a return channel formed therein connecting the first channel and second channel to facilitate movement of the bearing elements between the first channel and second channel.

In another embodiment, a method for processing a substrate is described. The method includes lowering a support pedestal disposed in a processing chamber to a position such that a plurality of lift pins suspended in openings in the support pedestal contact a surface in a lower portion of the processing chamber, further lowering the support pedestal while each of the plurality of lift pins are guided along one or more of a plurality of bearing elements contained in a first set of radially aligned channels containing a first plurality of the plurality of bearing elements and a second set of radially aligned channels containing a second plurality of the plurality of bearing elements, each of the first plurality of bearing elements and second plurality of bearing elements being free to move between the radially aligned channels, extending a robot having a substrate thereon into the processing chamber to a position above the lift pins, lowering the robot until the substrate rests on the lift pins, and retracting the robot from the processing chamber.

### BRIEF DESCRIPTION OF THE DRAWINGS

So that the manner in which the above-recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1A is a schematic cross-sectional view of one embodiment of a processing system having a substrate support.

FIG. 1B is a schematic cross-sectional view of the processing chamber of FIG. 1A showing the substrate support in a transfer position.

FIG. 1C is an enlarged view of a roller bushing and a portion of the substrate support of FIG. 1A.

FIG. 2A is a side cross-sectional view of one embodiment of a roller bushing.

FIG. 2B is a top cross-sectional view of the roller bushing taken along lines 2B-2B of FIG. 2A.

FIG. 3 is an isometric view of an end cap.

FIG. 4 is an exploded isometric view of the roller bushing of FIGS. 2A and 2B.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

Embodiments of the invention generally relate to a linear motion device for guiding a pin utilizing rolling friction. In one embodiment described herein, a method and apparatus for supporting, transferring and/or handling flexible media is described. The method and apparatus includes a support device that is particularly suitable for rectangular media having at least one major side with a surface area greater than one square meter, such as greater than about two square meters, or larger. In one embodiment, a support device for supporting a lift pin used to support or facilitate transfer the flexible, rectangular media is described. The support device may be used in a vacuum chamber adapted to deposit materials on the media to form electronic devices such as thin film transistors, organic light emitting diodes, photovoltaic devices or solar cells. The flexible media as described herein may be thin sheet of metal, plastic, organic material, silicon, glass, quartz, or polymeric materials, among other suitable materials.

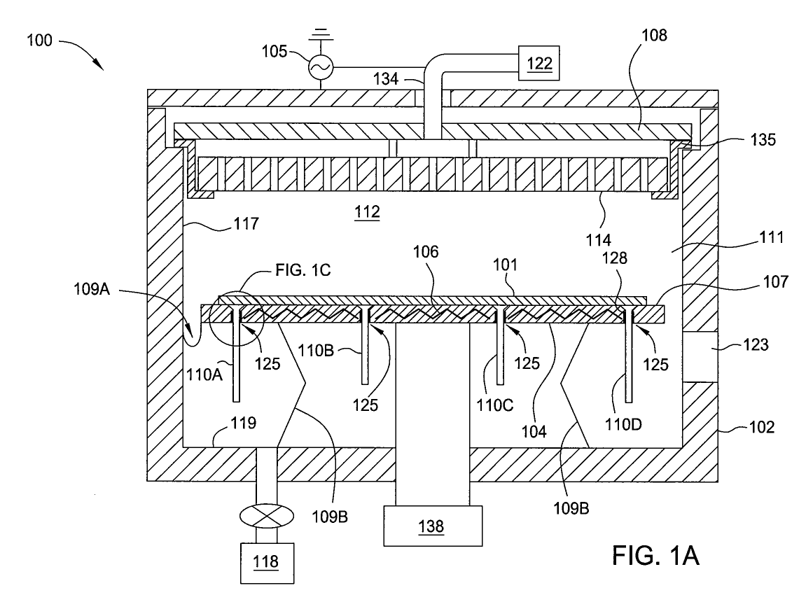

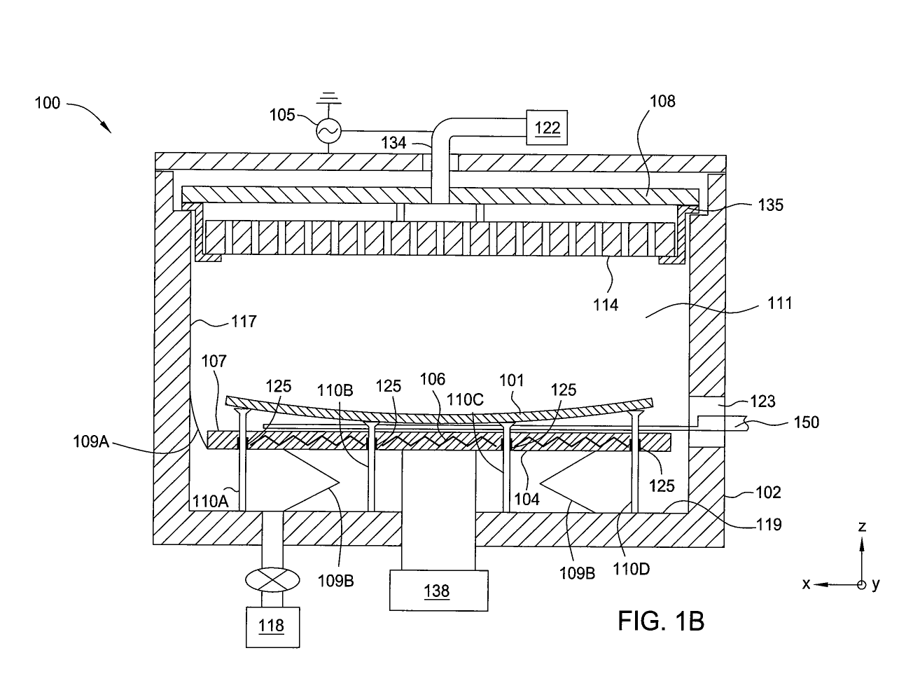

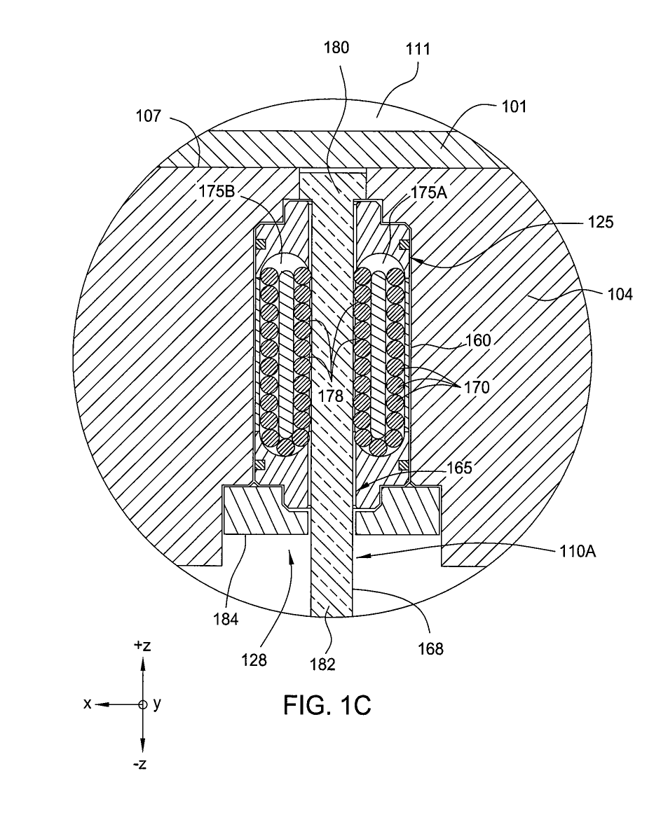

FIG. 1A is a schematic cross-sectional view of one embodiment of a processing system 100. In one embodiment, the processing system 100 is configured to process flexible media, such as a large area substrate 101, using plasma to form structures and devices on the large area substrate 101. The structures formed by the processing system 100 may be adapted for use in the fabrication of liquid crystal displays (LCD's), flat panel displays, organic light emitting diodes (OLED's), or photovoltaic cells for solar cell arrays. The substrate 101 may be thin sheet of metal, plastic, organic material, silicon, glass, quartz, or polymer, among others suitable materials. The substrate 101 may have a surface area greater than about 1 square meter, such as greater than about 2 square meters. The structures may include one or more junctions used to form part of a thin film photovoltaic device or solar cell. In another embodiment, the structures may be a part of a thin film transistor (TFT) used to form a LCD or TFT type device. It is also contemplated that the processing system 100 may be adapted to process substrates of other sizes and types, and may be used to fabricate other structures.

As shown in FIG. 1A, the processing system 100 generally comprises a chamber body 102 including a sidewall 117, a bottom 119 and a lid 108 defining a processing volume 111. A support pedestal or substrate support 104 is disposed in the processing volume 111 opposing a showerhead assembly 114. The substrate support 104 is adapted to support the substrate 101 on an upper or support surface 107 during processing. The substrate support 104 is also coupled to an actuator 138 configured to move the substrate support 104 at least vertically to facilitate transfer of the substrate 101 and/or adjust a distance between the substrate 101 and a showerhead assembly 114. One or more lift pins 110A-110D extend through the substrate support 104 through respective roller bushings 125. Each of the lift pins 110A-110D are movably disposed within a dedicated support device, such as a roller bushing 125 that is disposed within openings 128 formed in the substrate support 104.

In the embodiment shown in FIG. 1A, the substrate support 104 is shown in a processing position near the showerhead assembly 114. In the processing position, the lift pins 110A-110D are adapted to be flush with or slightly below the support surface 107 of the substrate support 104 to allow the substrate 101 to lie flat on the substrate support 104. A processing gas source 122 is coupled by a conduit 134 to deliver process gases through the showerhead assembly 114 and into the processing volume 111. The processing system 100 also includes an exhaust system 118 configured to apply and/or maintain negative pressure to the processing volume 111. A radio frequency (RF) power source 105 is coupled to the showerhead assembly 114 to facilitate formation of a plasma in a processing region 112. The processing region 112 is generally defined between the showerhead assembly 114 and the support surface 107 of the substrate support 104.

The showerhead assembly 114, lid 108, and the conduit 134 are generally formed from electrically conductive materials and are in electrical communication with one another. The chamber body 102 is also formed from an electrically conductive material. The chamber body 102 is generally electrically insulated from the showerhead assembly 114. In one embodiment, the showerhead assembly 114 is mounted on the chamber body 102 by an insulator 135. In one embodiment, the substrate support 104 is also electrically conductive, and the substrate support 104 is adapted to function as a shunt electrode to facilitate a ground return path for RF energy.

A plurality of electrical return devices 109A, 109B may be coupled between the substrate support 104 and the sidewall 117 and/or the bottom 119 of the chamber body 102. Each of the return devices 109A, 109B are flexible and/or spring-like devices that bend, flex, or are otherwise selectively biased to contact the substrate support 104, the sidewall 117 and/or the bottom 119. In one embodiment, at least a portion of the plurality of return devices 109A, 109B are thin, flexible straps that are coupled between the substrate support 104, the sidewall 117 and/or the bottom 119. In one example, the substrate support 104 may be coupled to an earthen ground through at least a portion of the plurality of return devices 109A, 109B. Alternatively or additionally, the return path may be directed by at least a portion of the plurality of return devices 109A, 109B back to the RF power source 105. In this embodiment, returning RF current will pass along the interior surface of the bottom 119 and/or sidewall 117 to return to the RF power source 105.

Using a process gas from the processing gas source 122, the processing system 100 may be configured to deposit a variety of materials on the large area substrate 101, including but not limited to dielectric materials (e.g., SiO₂, SiOₓN_{y}, derivatives thereof or combinations thereof), semiconductive materials (e.g., Si and dopants thereof), barrier materials (e.g., SiNₓ, SiOₓN_{y} or derivatives thereof). Specific examples of dielectric materials and semiconductive materials that are formed or deposited by the processing system 100 onto the large area substrate may include epitaxial silicon, polycrystalline silicon, amorphous silicon, microcrystalline silicon, silicon germanium, germanium, silicon dioxide, silicon oxynitride, silicon nitride, dopants thereof (e.g., B, P, or As), derivatives thereof or combinations thereof. The processing system 100 is also configured to receive gases such as argon, hydrogen, nitrogen, helium, or combinations thereof, for use as a purge gas or a carrier gas (e.g., Ar, H₂, N₂, He, derivatives thereof, or combinations thereof). One example of depositing silicon thin films on the large area substrate 101 using the system 100 may be accomplished by using silane as the precursor gas in a hydrogen carrier gas. The showerhead assembly 114 is generally disposed opposing the substrate support 104 in a substantially parallel manner to facilitate plasma generation therebetween.

A temperature control device 106 is also disposed within the substrate support 104 to control the temperature of the substrate 101 before, during, or after processing. In one aspect, the temperature control device 106 comprises a heating element to preheat the substrate 101 prior to processing. In this embodiment, the temperature control device 106 may heat the substrate support 104 to a temperature between about 200° C. and 250° C. During processing, temperatures in the processing region 112 reach or exceed 400° C. and the temperature control device 106 may comprise one or more coolant channels to cool the substrate 101. In another aspect, the temperature control device 106 may function to cool the substrate 101 after processing. Thus, the temperature control device 106 may be coolant channels, a resistive heating element, or a combination thereof.

FIG. 1B is a schematic cross-sectional view of the processing system 100 of FIG. 1A illustrating the substrate support 104 in a transfer position. In the transfer position, the substrate 101 is positioned in a spaced-apart relationship relative to the support surface 107 of the substrate support 104. In the spaced-apart position, the substrate 101 may be removed by a robotic device. In one embodiment, the substrate 101 is lifted away from the support surface 107 in an edge first/center last manner. The edge first/center last transfer method causes the substrate 101 to be lifted and supported by the lift pins 110A-11D in a bowed orientation. During processing, electrostatic charges build up between the substrate 101 and the support surface 107. After processing, a portion of this electrostatic charge remains and serves to adhere the substrate 101 to the support surface 107. The edge first/center last lifting method eases lifting of the substrate 101 by minimizing the force needed to break the residual electrostatic attraction and/or redistribute residual electrostatic forces that results in less lifting force being used. Likewise, the transfer method for a to-be-processed substrate is performed in a center first/edge last manner. The center first/edge last lowering method allows better contact between the substrate 101 and the support surface 107. For example, any air that is present between the support surface 107 and the substrate 101 is allowed to escape as the substrate 101 is lowered toward the substrate support 104.

In order to promote transfer of the substrate 101 in a bowed orientation, the lift pins 110A-110D are divided into groups, such as outer lift pins for perimeter support and inner lift pins for center support. The groups of lift pins are actuated at different times and/or adapted to extend different lengths (or heights) above the support surface 107 to position the substrate 101 in the bowed orientation. In one embodiment, the outer lift pins 110A, 110D are longer than the inner lift pins 1108, 110C. In this embodiment, the lift pins 110A-110D are adapted to contact the bottom 119 of the chamber body 102 and support the substrate 101 when the substrate support 104 is lowered by the actuator 138. The different lengths of the lift pins 110A, 110D and 1108, 110C allow the substrate 101 to be raised (or lowered) in a bowed orientation. In the transfer position, the support surface 107 of the substrate support 104 is substantially aligned with a transfer port 123 formed in the sidewall 117 which allows a blade 150 of a robot to move in the X direction between or around the lift pins 110A-110D, and between the substrate 101 and the support surface 107. To remove the substrate from this position, the blade 150 moves vertically upwards (Z direction) to lift the substrate 101 from the lift pins 110A-110D. The blade-supported substrate may then be removed from the chamber body 102 by retracting the blade 150 in the opposite X direction. Likewise, to place a to-be-processed substrate 101 on the lift pins 110A-110D, the blade 150 moves vertically downwards (Z direction) to position the substrate on the extended lift pins 110A-110D.

FIG. 1C is an enlarged view of the roller bushing 125 and a portion of the substrate support 104 of FIG. 1A. The roller bushing 125 includes a body 160 having a bore 165 formed therethrough to receive the lift pin 110A. The body 160 may be press-fit into the opening 128 from a lower surface of the substrate support 104 and/or coupled to the substrate support 104 by a base cap 184. The base cap 184 may be coupled to the substrate support 104 by threads or fasteners, such as screws (not shown) or by a press-fit. The bore 165 is sized slightly larger than the lift pin 110A to allow the lift pin 110A to move within the bore 165 along a longitudinal axis of the bore 165. The lift pin 110A includes a head 180 and a shaft 182. The head 180 prevents the lift pin 110A from moving completely through the bore 165, thereby allowing the lift pin 110A to be suspended when the substrate support 104 is in a raised position as shown in FIG. 1A. The head 180 may be an enlarged portion of the shaft 182 of the lift pin 110A or a separate element that is fastened to the shaft 182 of the lift pin 110A. In one embodiment, the head 180 has a first diameter and the shaft 182 has a second diameter that is less than the diameter of the head 180 of the lift pin 110A. In another embodiment, the head 180 may be flared of frusto-conically shaped such that the head 180 includes a first diameter that is substantially equal to the diameter of the shaft of the lift pin 110A and transitions to a second diameter that is greater than the first diameter.

The suspension of the lift pin 110A allows the lift pin 110A to move with the substrate support 104 during vertical movement of the substrate support 104. The suspension of the lift pin 110A also allows the lower end of the lift pin 110A (end opposite the head 180) to be free-floating such that any lateral misalignment between the bottom 119 (FIGS. 1A and 1B) of the chamber body 102 and the lower end of the lift pin 110A will not cause binding or breakage of the lift pin 110A.

An outer surface 168 of the lift pin 110A is contacted by one or more bearing elements 170 that are disposed in circular tracks or raceways 175A, 175B formed in the body 160. Each of the raceways 175A, 175B include a longitudinal slit 178 that allows a portion of the bearing elements 170 to extend partially into the bore 165 and contact the outer surface 168 of the lift pin 110A. In this embodiment, the roller bushing 125 includes four discrete raceways (only raceways 175A, 175B are visible in this Figure) although three or more raceways may be utilized. Each of the bearing elements 170 may be a roller element, such as a ball bearing or a spherical body. Each of the bearing elements 170 are made of an inert material that is not reactive with process gases or plasma, such as a ceramic or crystal material, such as sapphire, ruby, quartz and combinations thereof.

In operation, when the substrate support 104 is in the processing position, as shown in FIG. 1A, the head 180 is disposed flush with or slightly lower than a plane of the support surface 107. In this manner, the head 180 fills any voids in the support surface 107 caused by placement of the body 160 in the substrate support 104. The body 160 and lift pin 110A are at least partially thermally conductive in order to transfer thermal energy to and from the substrate 101 and substrate support 104. The body 160, in combination with the supported head 180, enhances heating or cooling of the substrate 101, which minimizes or eliminates “cold spots” on the substrate 101. The uniform temperature distribution enabled by the roller bushing 125 facilitates uniform deposition on the substrate 101.

When the substrate support 104 is moving to a transfer position (lowered in the −Z direction), the body 160 maintains the lift pin 110A in a substantially vertical orientation (Z direction) until the lower end of the lift pin 110A contacts the bottom 119 (FIGS. 1A and 1B) of the chamber body 102. After contacting the bottom 119 of the chamber body 102, the lift pin 110A becomes stationary relative to the substrate support 104 which continues movement in the −Z direction. As the substrate support 104 moves relative to the lift pin 110A, the bearing elements 170 move in the raceways 175A, 175B of the body 160 in a recirculating mode. The movement of the substrate support 104 causes the head 180 to extend away from the support surface 107 in the +Z direction, lifting a spacing the substrate 101 from the support surface 107 of the substrate support 104.

During this −Z directional movement of the substrate support 104, the bearing elements 170 move relative to each other and allow the body 160 to move relative to the lift pin 110A. In one embodiment, the bearing elements 170 that contact the lift pin 110A move in a direction that is opposite to the movement of the lift pin 110A. In another embodiment, when sufficient contact is made between the lift pin 110A and the bearing elements 170, at least a portion of the bearing elements 170 move within the raceways 175A, 175B in opposing directions. For example, as the substrate support 104 is moving in the +Z direction, the bearing elements 170 in the raceway 175A move in a clockwise direction while the bearing elements 170 in the raceway 175B move in a counterclockwise direction. Likewise, when the substrate support 104 is moving in a −Z direction (such as during transfer of a to-be-processed substrate) the movement of the bearing elements 170 in the raceways 175A, 175B is reversed.

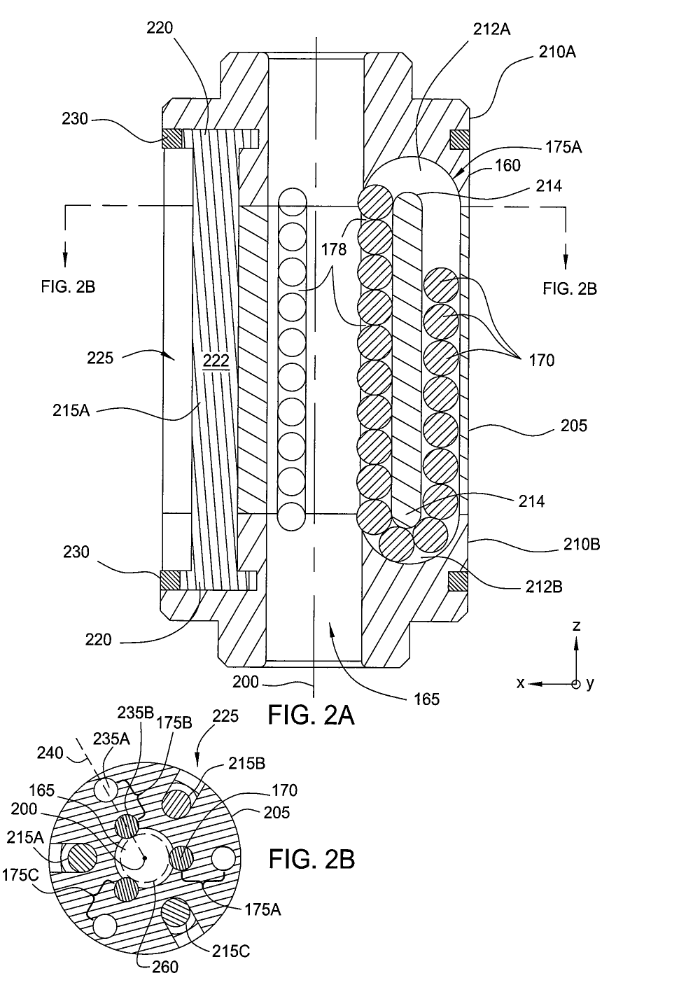

FIG. 2A is a side cross-sectional view of one embodiment of a roller bushing 125 and FIG. 2B is a top cross-sectional view of the roller bushing 125 taken along lines 2B-2B of FIG. 2A. In this embodiment, the roller bushing 125 includes three raceways 175A (175B and 175C are shown in FIG. 2B) disposed concentrically and/or radially from a longitudinal axis 200 of the roller bushing 125. Each of the raceways 175A include a longitudinal slit 178 in the inner wall of the body 160, allowing a portion of the bearing elements 170 to extend into the bore 165. The body 160 includes a central housing 205 and end caps 210A, 210B at opposing ends of the housing 205. In one embodiment, each of the end caps 210A, 210B are part of the raceway 175A. For example, the end caps 210A, 210B include a return groove 212A, 212B, respectively, to provide a recirculating path for the plurality of bearing elements 170. In one embodiment, each of the raceways 175A-175C include two discrete channels formed longitudinally through the body 160 or parallel to the bore 165 and the return grooves 212A, 212B (in reference to raceway 175A) connect the two channels. The return grooves 212A, 212B are substantially U-shaped grooves formed in a surface of the end caps 210A, 210B to allow the bearing elements 170 to enter from one channel and be directed to another channel of the respective raceway 175A-175C. In one embodiment, the upper and lower ends of the housing 205 include a protrusion or ridge 214 extending away from the ends of the housing 205 to form an inner surface for the raceway 175A.

Each of the end caps 210A, 210B are secured to each other and/or the housing 205 by at least one retaining member 215A (215B and 215C are shown in FIG. 2B). The at least one retaining member 215A may be a fastener, such as a pin, bolt or screw, that fastens the end caps 210A, 210B to each other and/or the housing 205. In one embodiment, the at least one retaining member 215A is a pin having enlarged heads 220 at each end of a shaft 222. In this embodiment, the heads 220 are received in respective slots formed in each end cap 210A, 210B such that the retaining member 215A retains each end cap 210A, 210B to the housing 205.

The materials used to make the roller bushing 125 are generally resistant to process chemistry and high temperatures. Examples include metallic materials, such as aluminum, anodized or non-anodized, stainless steel, or alloys thereof. In one embodiment, the roller bushing 125 comprises a dielectric or inert material, such as ceramic. In one embodiment, the housing 205, the end caps 210A, 210B, the bearing elements 170 and the retaining members 215A-215C are made from a ceramic material that is resistant to process chemistry and temperatures in excess of about 400° C. to about 1,000° C.

In this embodiment, the shaft 222 of the retaining member 215A includes a smaller outer dimension than the heads 220 and the shaft 222 is disposed in a U-shaped groove or channel 225 formed in the outer surface of the housing 205. A retaining ring 230, such as a snap ring or split ring, secures the retaining member 215A in each end cap 210A, 210B. The channel 225 formed in the outer surface of the housing 205 allows the retaining member 215A to be readily inserted or removed from the housing 205 when the retaining ring 230 is removed. The retaining rings 230 may be made from a material that is resistant to process chemistry and heat while retaining spring-like properties. The materials for the retaining rings may be heat resistant plastics or metallic materials, such as aluminum, stainless steel, among other metals or alloys thereof. In one example, the retaining rings 230 are made from aluminum, ceramics or ceramic fibers.

The roller bushing 125 is constructed to have a substantially equal peripheral or outside dimension to facilitate a press-fit or close-fit insertion into the openings 128 of the substrate support 104 (FIG. 1A). The housing 205, end caps 210A, 210B and retaining rings 230 are dimensioned to form a smooth peripheral outer surface to ease installation or removal and/or minimize particle generation during installation or removal. In one embodiment, the outer diameter of the housing 205, end caps 210A, 210B and retaining rings 230 are substantially equal.

FIG. 2B is a top cross-sectional view of the roller bushing 125 taken along lines 2B-2B of FIG. 2A. Each of the raceways 175A-175C include a first channel 235A and a second channel 235B. Each of the first channels 235A and second channels 235B are spaced apart from each other and may be disposed in a stacked orientation, concentrically or in a co-radial relationship within the housing 205. For example, each of the first channels 235A and second channels 235B are disposed in the same radial plane 240 relative to the longitudinal axis 200 but in different radial distances from the longitudinal axis 200. In one embodiment, the center of each of the first channels 235A is disposed radially outward of the respective second channel 235B.

In one embodiment, each of the raceways 175A-175C are disposed in radial axes that are positioned at substantially equal intervals. For example, each of the raceways 175A-175C are disposed in 120 degree intervals such that the raceways are substantially equally spaced. In another embodiment, each of the U-shaped channels 225 are formed between each of the raceways 175A-175C. In a specific embodiment, each of the channels 225 is offset by about 60 degrees from the radial plane of each raceway 175A-175C. In one example, the channels 225 are positioned in 120 degree intervals. In another example, the channels 225 are positioned at 60 degree intervals from the radial axes of each of the raceways 175A-175C. Other positions for the raceways 175A-175C are contemplated, such as unequal spacing or intervals as well as intervals of 180 degrees, 90 degrees, 45 degrees, depending on the number of raceways.

As can be seen in FIG. 2B, the surfaces of the bearing elements 170 that protrude into the bore 165 form a diametrical interface 260 that is slightly greater than a diameter of the lift pin 110A (not shown in this Figure). The larger diametrical interface 260 allows the lift pin 110A to rotate and/or move relative to the bore 165 in a slightly offset relationship to the longitudinal axis 200. In one embodiment, the diameter of the lift pin 110A is between about 0.18 inches to about 0.30 inches, such as about 0.25 inches, and the diametrical interface 260 is between about 0.20 inches to about 0.32 inches, such as about 0.255 inches.

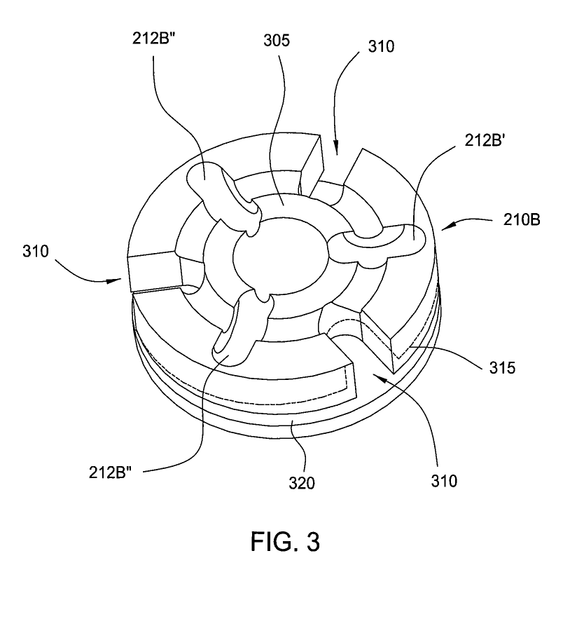

FIG. 3 is an isometric view of an end cap 210B showing the side that contacts the housing 205. The end cap 210B is substantially similar to the end cap 210A. The end cap 210B includes a plurality of return grooves 212B′, 212B″ and 221B′″ that are configured to align with the raceways 175A-175C in the housing 205. Also shown is an annular groove 305 that is positioned on the same radial position as the ridge 214 (shown in FIG. 2A). Also shown is a plurality of U-shaped grooves or channels 310 that receive the head 220 and a portion of the shaft of the retaining member 215A and other retaining members (not shown in this Figure). Each channel 310 includes a keyway 315 (shown in phantom) that is sized to receive the head 220 of the retaining member 215A. Additionally, a circumferential groove 320 is formed in a periphery of the end cap 210B that is adapted to receive the retaining ring 230 (shown in FIG. 2A).

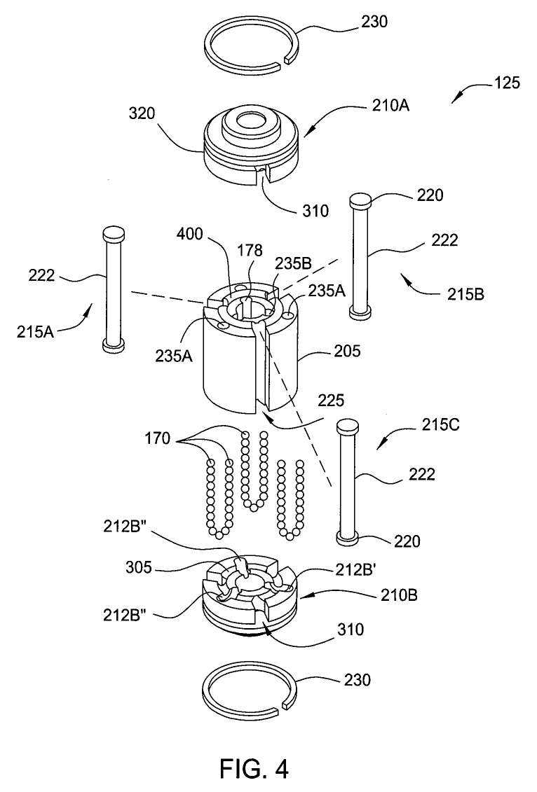

FIG. 4 is an exploded isometric view of the roller bushing 125 of FIGS. 2A and 2B. In this Figure, the housing 205 is depicted more clearly to show an annular protrusion or ridge 400 that is disposed between each of the first channels 235A and second channels 235B. In one embodiment, the annular ridge 400 is an extension of the ridge 214 shown in FIG. 2A and is present on the lower surface of the housing 205 but is not seen in this view. Like the ridge 214, the annular ridge 400 provides an inner surface to contain the bearing elements 170 in the recirculating path. In this embodiment, the annular ridge 400 is received in the channel 310 formed in the end caps 210A. 210B (only seen in 210B in this view). The annular ridge may also function as an indexing feature when assembling the roller bushing 125. Also shown is a plurality of return grooves 212B′, 212B″ and 221B′″ in the end cap 210B that are aligned with the respective raceways 175A-175C when assembled. While not seen in this view, end cap 210A is similarly constructed.

An assembly method for the roller bushing 125 is also described herein. The end cap 210B is brought into contact with a lower end of the housing 205 and the return grooves 212B′, 212B″ and 221B′″ in the end cap 210B are aligned with the respective raceways 175A-175C. The end cap 210B and housing 205 are not fastened at this point and are held together using gravity, an operator's hand(s), a clamp, or other fixture. The bearing elements 170, which in this embodiment are ball bearings, may be fed into one or both of the first and second channels 235A, 235B. In one embodiment, the number of bearing elements that are inserted into the channels 235A, 235B should fill each raceway 175A-175C between half full to full or near full capacity. In one example, each of the raceways 175A-175C, including the return grooves 212B′, 212B″ and 221B′″, are filled to about three-fourths capacity. In one aspect, the number of bearing elements 170 should be substantially equal in each raceway 175A-175C.

Next, the end cap 210A is brought into contact with the upper end of the housing 205 and the return grooves in the end cap 210A are aligned with the first and second channels 235A, 235B. The end caps 210A, 210B and the housing 205 may be held together while the retaining members 215A-215C are inserted into the U-shaped channels 225, 310 from the side of the housing 205. After the retaining members 215A-215C are inserted into the channels 225, 310, the retaining rings 230 may be inserted into the circumferential grooves 320, which secures the retaining members 215A-215C, holding the end caps 210A, 210B and the housing 205 together. The assembled roller bushing 125 may be inserted into an opening 128 formed in the substrate support 104 (FIG. 1C) and a lift pin 110A may be inserted into the bore 165. During insertion of the roller bushing 125 into the opening 128, the retaining rings 230 may be removed from the circumferential grooves 320, if desired, as the opening 128 is sized to retain the retaining rings 230.

While the foregoing is directed to embodiments of the invention, other and further embodiments of the invention may be devised without departing from the basic scope thereof. cm What is claimed is:

1. A support pedestal for a vacuum chamber, comprising;
a body having a having a plurality of openings formed between two major sides of the body; and
a roller bushing disposed in at least one of the plurality of openings, the roller bushing comprising:
a tubular body including an outer perimeter and a bore formed therethrough;
at least three raceways formed at least partially in the body, the at least three raceways containing a plurality of bearing elements, each of the at least three raceways comprising:
a first channel; and
a second channel parallel to and radialy separated from the first channel, the second channel including a longitudinal slit allowing at least a portion of the plurality of bearing elements to extend into the bore; and
a lift pin disposed in the bore.

2. The support pedestal of claim 1, wherein the first channel is disposed in a first radial plane and a first radial dimension relative to a centerline of the bore, and the second channel is disposed in the first radial plane in a second radial dimension relative to the centerline of the bore, the second radial dimension being less than the first radial dimension.

3. The support pedestal of claim 1, wherein the roller bushing further comprises:
a first cap disposed at a first end of the tubular body; and
a second cap disposed at a second end of the tubular body.

4. The support pedestal of claim 3, wherein each cap includes a plurality of return channels formed therein, each return channel connecting a respective pair of the first and second channels to facilitate movement of the bearing elements between the first and second channels.

5. The support pedestal of claim 3, wherein the first cap is coupled to the second cap through the body by a plurality of retaining members.

6. The support pedestal of claim 1, wherein each of the plurality of bearing elements are selected from the group consisting of roller elements, needle bearings, ball bodies, or combinations thereof.

7. The support pedestal of claim 1, wherein the tubular body and each of the plurality of bearing elements are fabricated from a ceramic material.

8. The support pedestal of claim 1, further comprising:
a base cap coupled to the body and securing the tubular body within the opening.

9. A support pedestal for a vacuum chamber, comprising;
an aluminum body having a having a plurality of openings formed between two major sides of the body; and
a roller bushing disposed in at least one of the plurality of openings, the roller bushing comprising:
a housing having a bore formed therethrough along a longitudinal axis;
at least two raceways formed at least partially in the housing having a plurality of bearing elements movably disposed therein, each of the at least two raceways comprising:
a first channel disposed in a first radial plane relative to the longitudinal axis; and
a second channel disposed in the first radial plane inward of the first channel, the second channel including a longitudinal slit allowing at least a portion of the plurality of bearing elements to extend into the bore; and
a first cap disposed at a first end of the housing and a second cap disposed at a second end of the housing, each cap including a return channel formed therein connecting the first channel and second channel to facilitate movement of the bearing elements between the first channel and second channel.

10. The roller bushing of claim 9, further comprising;
a plurality of retaining members, each of the retaining members having a first end captured in the first cap by a first retaining ring, and a second end captured in the second cap by a second retaining ring.

11. The roller bushing of claim 9, wherein the housing includes at least two longitudinal grooves formed in an outer surface of the housing, each of the longitudinal grooves adapted to receive the retaining members.

12. The roller bushing of claim 11, wherein each raceway is separated by one of the at least two longitudinal grooves.

13. The roller bushing of claim 9, wherein the housing includes an annular ridge at opposing ends thereof, the annular ridge separating the first channel from the second channel.

14. The roller bushing of claim 13, wherein each cap includes an annular channel that receives the annular ridge.

15. The roller bushing of claim 9, wherein each of the plurality of bearing elements are selected from the group consisting of roller elements, needle bearings, ball bodies, or combinations thereof.

16. The roller bushing of claim 15, wherein the housing and the bearing elements are made of a ceramic material.

17. A method for processing a substrate, comprising:
lowering a support pedestal disposed in a processing chamber to a position such that a plurality of lift pins suspended in openings in the support pedestal contact a surface in a lower portion of the processing chamber;
further lowering the support pedestal while each of the plurality of lift pins are guided along one or more of a plurality of bearing elements contained in a first set of radially aligned channels containing a first plurality of the plurality of bearing elements and a second set of radially aligned channels containing a second plurality of the plurality of bearing elements, each of the first plurality of bearing elements and second plurality of bearing elements being free to move between the radially aligned channels;
extending a robot blade having a substrate thereon into the processing chamber to a position above the lift pins;
lowering the robot blade until the substrate rests on the lift pins; and
retracting the robot blade from the processing chamber.

18. The method of claim 17, further comprising:
raising the support pedestal to a position in contact with the substrate.

19. The method of claim 18, further comprising:
applying radio frequency power to an area between the support pedestal and a showerhead assembly within the processing chamber to form a plasma; and
forming one more devices on the substrate.

20. The method of claim 19, further comprising:
lowering the support pedestal to a position which causes the plurality of lift pins to contact the surface in the lower portion of the processing chamber to space the substrate away from the support pedestal.
